(19) United States
(12) Patent Application Publication
(10) Pub. No.: US 2025/0255105 A1
(43) Pub. Date: Aug. 7, 2025

(54) DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Ju Hyun LEE, Yongin-si (KR); Yung Bin CHUNG, Yongin-si (KR)

(73) Assignee: Samsung Display Co., LTD., Yongin-si (KR)

(21) Appl. No.: 18/892,936

(22) Filed: Sep. 23, 2024

(30) Foreign Application Priority Data
Feb. 5, 2024 (KR) 10-2024-0017138

(51) Int. Cl. H10K 59/122; G02B 27/01; H10K 59/12

(52) U.S. Cl. CPC H10K 59/122; H10K 59/1201; G02B 27/0172; G02B 2027/0178

(57) ABSTRACT

A display device includes a substrate including an emission area and a non-emission area; a bank member disposed on the emission area of the substrate and including an undercut portion; a pixel electrode disposed on the bank member; a light emitting layer on the pixel electrode; a residual pattern layer disposed in the non-emission area of the substrate, including the same material as the pixel electrode, and spaced apart from the pixel electrode; and a pixel defining layer disposed on the residual pattern layer and in contact with the bank member, the pixel electrode and the light emitting layer, wherein the bank member includes a first bank layer and a second bank layer including a tip portion protruding toward the non-emission area more than the side surface of the first bank layer.

### CROSS-REFERENCE TO RELATED APPLICATION(S)

This application claims priority to and benefits of Korean Patent Application No. 10-2024-0017138 under 35 U.S.C. § 119, filed on Feb. 5, 2024, in the Korean Intellectual Property Office, the entire contents of which are incorporated herein by reference.

### BACKGROUND

### 1. Technical Field

Embodiments relate to a display device and a method for manufacturing the display device.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit providing light to a display panel because each of pixels of the display panel includes light emitting elements that emit light by themselves.

Recently, the display devices have been applied to glasses-type devices for providing virtual reality and augmented reality. The display device is implemented in a very small size of 2 inches or less in order to be applied to the glasses-type device, but should have a high pixel integration degree in order to be implemented with high resolution. For example, the display device may have a high pixel integration degree of 1,000 pixels per inch (PPI) or more.

In case that the display device is implemented in the very small size but has the high pixel integration degree as described above, areas of emission areas where light emitting elements are disposed are reduced, and thus, it is difficult to implement light emitting elements separated from each other for each emission area by a mask process.

### SUMMARY

Embodiments provide a method of manufacturing a display device capable of improving a process ease and process simplicity through providing a high-resolution display device in which a gap between pixel electrodes is reduced.

However, aspects of the disclosure are not restricted to those set forth herein. The above and other aspects of the disclosure will become more apparent to one of ordinary skill in the art to which the disclosure pertains by referencing the detailed description of the disclosure given below.

Detailed contents of other embodiments are described in a detailed description and are illustrated in the drawings.

According to an aspect of the disclosure, a display device may include a substrate including an emission area and a non-emission area; a bank member disposed on the emission area of the substrate and including an undercut portion; a pixel electrode disposed on the bank member; a light emitting layer on the pixel electrode; a residual pattern layer disposed in the non-emission area of the substrate and spaced apart from the pixel electrode, the residual pattern layer and the pixel electrode including a same material; and a pixel defining layer disposed on the residual pattern layer and in contact with the bank member, the pixel electrode and the light emitting layer, wherein the bank member may include a first bank layer and a second bank layer including a tip portion protruding toward the non-emission area more than the side surface of the first bank layer.

In an embodiment, the first bank layer and the second bank layer may include different metals.

In an embodiment, the first bank layer may include titanium, and wherein the second bank layer may include at least one of niobium, vanadium, and tantalum.

In an embodiment, the first bank layer may include a first side surface facing the non-emission area, and wherein an undercut portion may be formed between the first side surface of the first bank layer and the tip portion of the second bank layer.

In an embodiment, the pixel defining layer may be in contact with an entire surface of the first side surface of the first bank layer.

In an embodiment, the pixel defining layer may fill the undercut portion formed between the first side surface and the tip portion of the second bank layer.

In an embodiment, the pixel defining layer may include at least one of silicon-based, epoxy-based, acrylic-based, and silicon-acrylic-based materials.

In an embodiment, the pixel defining layer may include hexamethyl disiloxane.

In an embodiment, a height of the first bank layer may be greater than a height of the second bank layer.

In an embodiment, the height of the first bank layer may be in a range of about 1,500 angstroms to and about 2,500 angstroms, and wherein the height of the second bank layer may be in a range of about 1,000 angstroms to about 2,000 angstroms.

In an embodiment, the second bank layer may include a first side surface facing the non-emission area and a first surface facing the light emitting layer, and wherein the pixel electrode entirely covers the first surface and may entirely contact the first surface of the second bank layer.

In an embodiment, the pixel electrode may cover the first side surface of the second bank layer and is in contact with the first side surface of the second bank layer.

In an embodiment, the pixel electrode may include a first layer disposed on the second bank layer and may include metal; and a second layer disposed on the first layer and including a transparent conductive oxide (TCO).

In an embodiment, the residual pattern layer may include a first residual pattern layer and a second residual pattern layer, the first residual pattern layer and the first layer may include a same material, the second residual pattern layer and the second layer may include a same material, and the second residual pattern layer may cover the first residual pattern layer.

In an embodiment, the pixel defining layer may be in contact with the second residual pattern layer, and wherein the pixel defining layer entirely may cover the residual pattern layer.

In an embodiment, the light emitting layer may include a first side surface facing the non-emission area and an inclination angle formed by the pixel electrode and the first side surface of the light emitting layer may be in a range of about 60 degrees to about 90 degrees.

According to an aspect of the disclosure, a method of manufacturing a display device may include forming a first bank layer on a substrate, and forming a second bank layer on a first bank layer; removing a portion of the first bank layer and the second bank layer so that the second bank layer may include a tip portion protruding than the side surface of the first bank layer; forming a pixel electrode on the second bank layer; forming a light emitting layer and a sacrificial layer on the pixel electrode, and then forming the pixel defining layer on an entire surface of the sacrificial layer; removing a portion of the pixel defining layer to expose the sacrificial layer; and removing the sacrificial layer to expose the light emitting layer.

In an embodiment, in the removing of the portion of the first bank layer, the first bank layer may have a high etch rate in respect to a same etchant than the second bank layer.

In an embodiment, in removing the sacrificial layer, the first bank layer and the second bank layer may have different etching resistances to an etchant removing the sacrificial layer.

In an embodiment, the light emitting layer may be formed by a photolithography process.

With a display device and a method for manufacturing the same according to an embodiment, the display device may include a bank member having undercut structures under pixel electrodes, such that a gap between a plurality of pixel electrodes may be reduced, and the bank member may include a first bank layer and a second bank layer having different etching rates so to provide ease and simplicity of the manufacturing method.

For example, with a display device and a method for manufacturing the same according to an embodiment, by forming a light emitting layer by a photolithography process, a gap between a plurality of light emitting layers may be reduced, and accordingly, a high-resolution display device may be provided and an ease and simplicity of the manufacturing method may be provided.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a head mounted electronic device according to an embodiment;

FIG. 2 is an exploded schematic perspective view of the head mounted electronic device of FIG. 1;

FIG. 3 is a schematic perspective view illustrating a head mounted electronic device according to an embodiment;

FIG. 4 is an exploded schematic perspective view illustrating a display device according to an embodiment;

FIG. 5 is a schematic cross-sectional view of a display panel according to an embodiment taken along line X1-X1′ in FIG. 4;

FIG. 6 is an enlarged schematic cross-sectional view schematically illustrating a light emitting element in FIG. 5;

FIG. 7 is an enlarged schematic cross-sectional view schematically illustrating a first emission area in FIG. 5;

FIG. 8 is an enlarged schematic cross-sectional view schematically illustrating a non-emission area disposed between a first emission area and a second emission area in FIG. 5; and

FIGS. 9 to 21 are schematic cross-sectional views illustrating a method for manufacturing a light emitting element layer and an encapsulation layer in FIG. 5.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

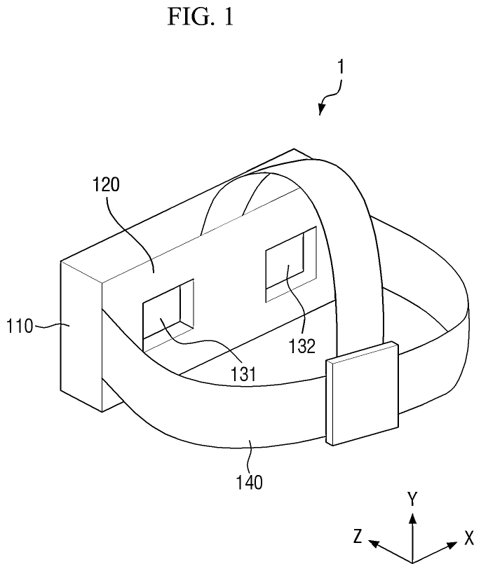

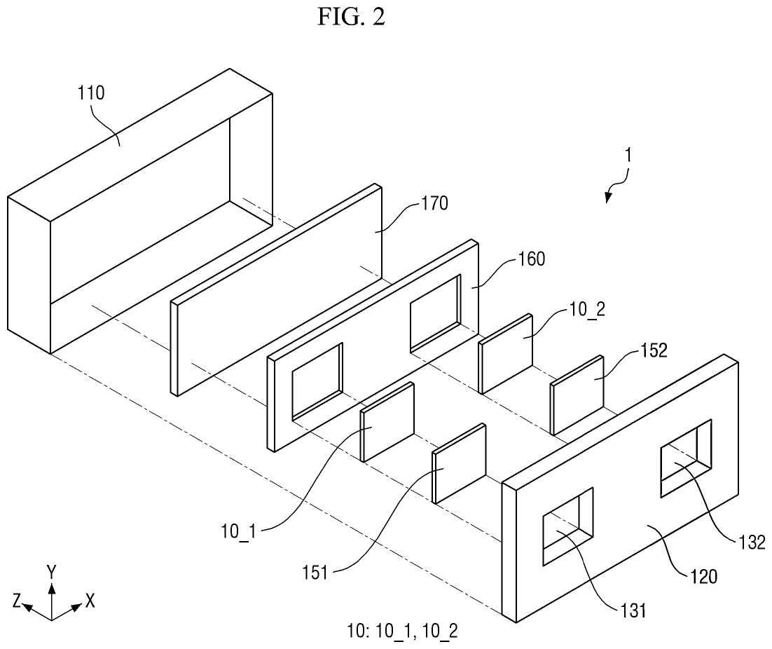

FIG. 1 is a schematic perspective view illustrating a head mounted electronic device 1 according to an embodiment. FIG. 2 is an exploded schematic perspective view of the head mounted electronic device 1 of FIG. 1.

Referring to FIGS. 1 and 2, a head mounted electronic device 1 according to an embodiment may include a display device 10, a display device housing portion 110, a housing portion cover 120, a first eyepiece 131, a second eyepiece 132, a head mounted band 140, a middle frame 160, a first optical member 151, a second optical member 152, and a control circuit board 170.

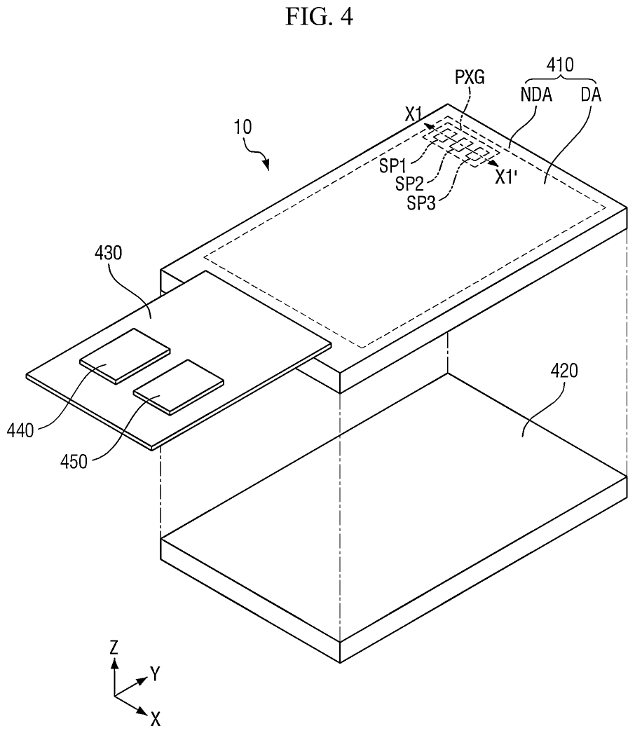

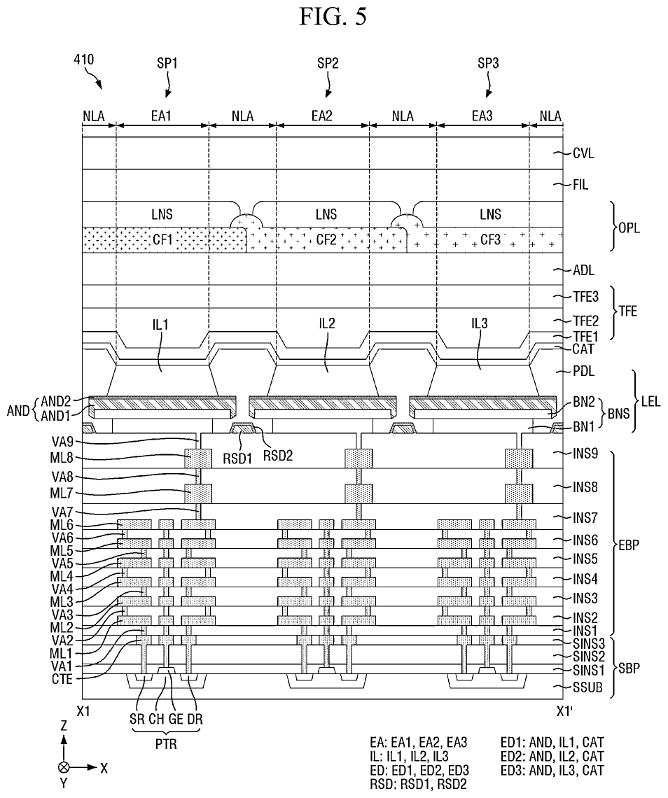

The display device 10 may include a first display device 10_1 and a second display device 10_2. The first display device 10_1 may provide an image to a user's left eye, and the second display device 10_2 may provide an image to a user's right eye. The display device 10 will be described in detail later with reference to FIGS. 4 and 5.

The first optical member 151 may be disposed between the first display device 10_1 and the first eyepiece 131, and the second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and disposed between the second display device 10_2 and the control circuit board 170. The middle frame 160 may function to support and fix the first display device 10_1, the second display device 10_2, and the control circuit board 170.

The control circuit board 170 may be disposed between the middle frame 160 and the display device housing portion 110. The control circuit board 170 may be connected to the first display device 10_1 and the second display device 10_2 through a connector. The control circuit board 170 may convert an image source input from the outside into digital video data, and transmit the digital video data to the first display device 10_1 and the second display device 10_2 through the connector.

The control circuit board 170 may transmit digital video data corresponding to a left eye image optimized for the user's left eye to the first display device 10_1 and transmit digital video data corresponding to a right eye image optimized for the user's right eye to the second display device 10_2. In another example, the control circuit board 170 may transmit the same digital video data to the first display device 10_1 and the second display device 10_2.

The display device housing portion 110 may function to house the display device 10, the middle frame 160, the first optical member 151, the second optical member 152, and the control circuit board 170. The housing portion cover 120 may be disposed to cover opened a surface of the display device housing portion 110. The housing portion cover 120 may include the first eyepiece 131 on which the user's left eye is disposed and the second eyepiece 132 on which the user's right eye is disposed. It has been illustrated in FIGS. 1 and 2 that the first eyepiece 131 and the second eyepiece 132 are separately disposed, but embodiments are not limited thereto. The first eyepiece 131 and the second eyepiece 132 may be merged as one eyepiece.

The first eyepiece 131 may be aligned with the first display device 10_1 and the first optical member 151, and the second eyepiece 132 may be aligned with the second display device 10_2 and the second optical member 152. Accordingly, a user may view an image of the first display device 10_1 magnified as a virtual image by the first optical member 151 through the first eyepiece 131, and may view an image of the second display device 10_2 magnified as a virtual image by the second optical member 152 through the second eyepiece 132.

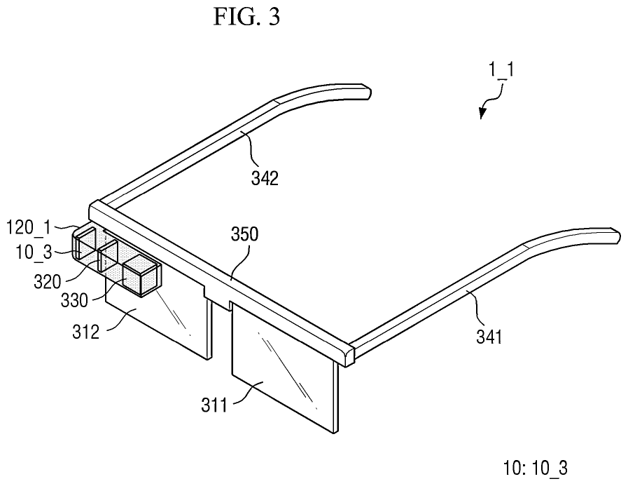

The head mounted band 140 may function to fix the display device housing portion 110 to a user's head so that the first eyepiece 131 and the second eyepiece 132 of the housing portion cover 120 may be maintained in a state in which they are disposed on the user's left eye and right eye, respectively. In case that the display device housing portion 110 is implemented to have a light weight and a small size, the head mounted electronic device 1 may include an eyeglass frame as illustrated in FIG. 3 instead of the head mounted band 140.

For example, the head mounted electronic device 1 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 3 is a schematic perspective view illustrating a head mounted electronic device 1 according to an embodiment.

Referring to FIG. 3, a head mounted electronic device 1_1 according to an embodiment may be a glasses-type electronic device in which a display device housing portion 120_1 is implemented to have a light weight and a small size. The head mounted electronic device 1_1 according to an embodiment may include a display device 10, a left eye lens 311, a right eye lens 312, a support frame 350, glasses frame legs 341 and 342, an optical member 320, an optical path conversion member 330, and a display device housing portion 120_1.

The third display device 10_3 may be substantially the same as the first display device 10_1 and the second display device 10_2 illustrated in FIG. 2. The display device 10 will be described later with reference to FIGS. 4 and 5.

The display device housing portion 120_1 may include the display device 10, the optical member 320, and the optical path conversion member 330. An image displayed on the display device 10 may be magnified by the optical member 320, converted in an optical path by the optical path conversion member 330, and provided to a user's right eye through the right eye lens 312. For this reason, a user may view an augmented reality image in which a virtual image displayed on the display device 10 through his/her right eye and a real image seen through the right eye lens 312 are combined with each other.

It has been illustrated in FIG. 3 that the display device housing portion 120_1 is disposed at a right end portion of the support frame 350, but embodiments are not limited thereto. For example, the display device housing portion 120_1 may be disposed at a left end portion of the support frame 350, and an image of the display device 10 may be provided to a user's left eye. In another example, the display device housing portions 120_1 may be disposed at both the left and right ends of the support frame 350, and the user may view an image displayed on the display device 10 through both his/her left and right eyes.

FIG. 4 is an exploded schematic perspective view illustrating a display device 10 according to an embodiment.

Referring to FIG. 4, the display device 10 according to an embodiment may be a device that displays a moving image or a still image. The display device 10 according to an embodiment may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 may be applied to televisions, laptop computers, monitors, billboards, or the Internet of Things (IOTs). In another example, the display device 10 may be applied to smart watches, watch phones, or head mounted displays (HMDs) to enable virtual reality and augmented reality experiences.

The display device 10 according to an embodiment may include a display panel 410, a heat dissipation layer 420, a circuit board 430, a driving circuit 440, and a power supply circuit 450.

The display panel 410 may have a shape similar to a rectangular shape in plan view. For example, the display panel 410 may have a shape similar to a rectangular shape, in plan view, having short sides in a first direction X and long sides in a second direction Y intersecting the first direction X. In the display panel 410, a corner where the short side in the first direction X and the long side in the second direction Y meet may be rounded at a selected curvature or right-angled. The shape of the display panel 410 in plan view is not limited to the rectangular shape, and may be a shape similar to other polygonal shapes, a circular shape, or an elliptical shape. A shape of the display device 10 in plan view may correspond to the shape of the display panel 410 in plan view, but embodiments are not limited thereto.

The display panel 410 may include a display area DA, which displays an image, and a non-display area NDA, which does not display an image.

A display area DA may be positioned at the center portion of the display panel 410, and may occupy most of an area of the display panel 410. The display area DA may include pixel groups PXG, and the pixel group PXG may be a minimum unit emitting white light. The pixel group PXG may include first to third pixels SP1, SP2, and SP3. The first to third pixels SP1, SP2, and SP3 may emit light of the same color or emit light of different colors. A non-display area NDA may surround an edge portion of the display area DA.

The heat dissipation layer 420 may overlap the display panel 410 in a third direction Z, which is a thickness direction of the display panel 410. The heat dissipation layer 420 may be disposed on a surface, for example, a rear surface, of the display panel 410. The heat dissipation layer 420 may function to dissipate heat generated from the display panel 410. The heat dissipation layer 420 may include a layer made of graphite or metal such as silver (Ag), copper (Cu), or aluminum (Al) having high thermal conductivity.

The circuit board 430 may be positioned on the non-display area NDA of the display panel 410 using a conductive adhesive member such as an anisotropic conductive film. The circuit board 430 may be a flexible printed circuit board or a flexible film having a flexible material. It has been illustrated in FIG. 4 that the circuit board 430 is unbent, but the circuit board 430 may be bent. For example, an end portion of the circuit board 430 may be disposed on the rear surface of the display panel 410. The end portion of the circuit board 430 may be an end opposite to another end portion of the circuit board 430 connected to pads of a pad area of the display panel 410 using the conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate panel driving voltages according to an external source voltage. For example, the power supply circuit 450 may generate a first driving voltage (e.g., VSS), a second driving voltage (e.g., VDD), and a third driving voltage (e.g., VINT) and supply the first driving voltage, the second driving voltage, and the third driving voltage to the display panel 410.

Each of the driving circuit 440 and the power supply circuit 450 may be formed as an integrated circuit (IC) and attached to a surface of the circuit board 430.

FIG. 5 is a schematic cross-sectional view of a display panel 410 according to an embodiment taken along line X1-X1′ in FIG. 4.

Referring to FIG. 5, the display panel 410 may include a semiconductor backplane SBP, a light emitting element backplane EBP, a light emitting element layer LEL, an encapsulation layer TFE, an optical layer OPL, and a cover layer CVL.

The semiconductor backplane SBP may include a semiconductor substrate SSUB including transistors PTR, semiconductor insulating films covering the transistors PTR, and contact terminals CTE electrically connected to the transistors PTR, respectively.

The semiconductor substrate SSUB may be a silicon substrate, a germanium substrate, or a silicon-germanium substrate. The semiconductor substrate SSUB may be a substrate doped with first-type impurities. Well regions may be disposed in an upper surface of the semiconductor substrate SSUB. The well regions may be regions doped with second-type impurities. The second-type impurities may be different from the first-type impurities described above. For example, in case that the first-type impurities are p-type impurities, the second-type impurities may be n-type impurities. In another example, in case that the first-type impurities are n-type impurities, the second-type impurities may be p-type impurities.

Each of the well regions may include a source region SR corresponding to a source electrode of the transistor PTR, a drain region DR corresponding to a drain electrode of the transistor PTR, and a channel region CH disposed between the source region SR and the drain region DA.

Each of the source region SR and the drain region DR may be a region doped with the first-type impurities. A gate electrode GE of the transistor PTR may overlap the well region in the third direction Z. The channel region CH may overlap the gate electrode GE in the third direction Z. The source region SR may be disposed on a side of the gate electrode GE, and the drain region DR may be disposed on the other side of the gate electrode GE.

A first insulating layer SINS1 may be disposed on the semiconductor substrate SSUB. The first insulating layer SINS1 may be formed as a silicon carbonitride (SiCN) or silicon oxide (SiOₓ)-based inorganic film, but embodiments are not limited thereto.

A second insulating layer SINS2 may be disposed on the first insulating layer SINS1. The second insulating layer SINS2 may be formed as a silicon oxide (SiOₓ)-based inorganic film, but embodiments are not limited thereto.

The contact terminals CTE may be disposed on the second insulating layer SINS2. Each of the contact terminals CTE may be connected to any one of the gate electrode GE, the source region SR, and the drain region DR of each of the transistors PTR through a hole penetrating through the first insulating layer SINS1 and the second insulating layer SINS2.

Each of the contact terminals CTE may be made of any one of copper (Cu), aluminum (Al), tungsten (W), molybdenum (Mo), chromium (Cr), gold (Au), titanium (Ti), nickel (Ni), and neodymium (Nd), or alloys thereof.

A third insulating layer SINS3 may be disposed on side surfaces of the contact terminals CTE. An upper surface of each of the contact terminals CTE may be exposed without being covered by the third insulating layer SINS3. The third insulating layer SINS3 may be formed as a silicon oxide (SiOₓ)-based inorganic film, but embodiments are not limited thereto.

The semiconductor substrate SSUB may be replaced with a glass substrate or a polymer resin substrate such as a polyimide substrate. For example, thin film transistors may be disposed on the glass substrate or the polymer resin substrate. The glass substrate may be a rigid substrate that is not bent, and the polymer resin substrate may be a flexible substrate that is bent or curved.

The light emitting element backplane EBP may include first to eighth metal layers ML1 to ML8, first to ninth vias VA1 to VA9, and first to ninth interlayer insulating layers INS1 to INS9.

The first to eighth metal layers ML1 to ML8 may function to implement circuits of the pixels SP1 to SP3 by connecting the contact terminals CTE exposed from the semiconductor backplane SBP to each other.

The first interlayer insulating layer INS1 may be disposed on the semiconductor backplane SBP. Each of the first vias VA1 may penetrate through the first interlayer insulating layer INS1 to be connected to the contact terminal CTE exposed from the semiconductor backplane SBP. Each of the first metal layers ML1 may be disposed on the first interlayer insulating layer INS1 and be connected to the first via VA1.

The second interlayer insulating layer INS2 may be disposed on the first interlayer insulating layer INS1 and the first metal layers ML1. Each of the second vias VA2 may penetrate through the second interlayer insulating layer INS2 to be connected to the exposed first metal layer ML1. Each of the second metal layers ML2 may be disposed on the second interlayer insulating layer INS2 and be connected to the second via VA2.

The third interlayer insulating layer INS3 may be disposed on the second interlayer insulating layer INS2 and the second metal layers ML2. Each of the third vias VA3 may penetrate through the third interlayer insulating layer INS3 to be connected to the exposed second metal layer ML2. Each of the third metal layers ML3 may be disposed on the third interlayer insulating layer INS3 and be connected to the third via VA3.

The fourth interlayer insulating layer INS4 may be disposed on the third interlayer insulating layer INS3 and the third metal layers ML3. Each of the fourth vias VA4 may penetrate through the fourth interlayer insulating layer INS4 to be connected to the exposed third metal layer ML3. Each of the fourth metal layers ML4 may be disposed on the fourth interlayer insulating layer INS4 and be connected to the fourth via VA4.

The fifth interlayer insulating layer INS5 may be disposed on the fourth interlayer insulating layer INS4 and the fourth metal layers ML4. Each of the fifth vias VA5 may penetrate through the fifth interlayer insulating layer INS5 to be connected to the exposed fourth metal layer ML4. Each of the fifth metal layers ML5 may be disposed on the fifth interlayer insulating layer INS5 and be connected to the fifth via VA5.

The sixth interlayer insulating layer INS6 may be disposed on the fifth interlayer insulating layer INS5 and the fifth metal layers ML5. Each of the sixth vias VA6 may penetrate through the sixth interlayer insulating layer INS6 to be connected to the exposed fifth metal layer ML5. Each of the sixth metal layers ML6 may be disposed on the sixth interlayer insulating layer INS6 and be connected to the sixth via VA6.

The seventh interlayer insulating layer INS7 may be disposed on the sixth interlayer insulating layer INS6 and the sixth metal layers ML6. Each of the seventh vias VA7 may penetrate through the seventh interlayer insulating layer INS7 to be connected to the exposed sixth metal layer ML6. Each of the seventh metal layers ML7 may be disposed on the seventh interlayer insulating layer INS7 and be connected to the seventh via VA7.

The eighth interlayer insulating layer INS8 may be disposed on the seventh interlayer insulating layer INS7 and the seventh metal layers ML7. Each of the eighth vias VA8 may penetrate through the eighth interlayer insulating layer INS8 to be connected to the exposed seventh metal layer ML7. Each of the eighth metal layers ML8 may be disposed on the eighth interlayer insulating layer INS8 and be connected to the eighth via VA8.

The contact terminals CTE of the semiconductor backplane SBP and the first to sixth metal layers ML1 to ML6 of the light emitting element backplane EBP may be connected to the drain region DA, the source region SR, and the gate electrode GE of the transistor PTR. The seventh and eighth metal layers ML7 and ML8 may not be connected to the source region SR and the gate electrode GE, but may be connected to the drain region DA.

The first to eighth metal layers ML1 to ML8 and the first to eighth vias VA1 to VA8 may be made of substantially the same material. Each of the first to eighth metal layers ML1 to ML8 and the first to eighth vias VA1 to VA8 may be made of any one of copper (Cu), aluminum (Al), tungsten (W), molybdenum (Mo), chromium (Cr), gold (Au), titanium (Ti), nickel (Ni), and neodymium (Nd), or alloys thereof. The first to eighth vias VA1 to VA8 may be made of substantially the same material. The first to eighth interlayer insulating layers INS1 to INS8 may be formed as silicon oxide (SiOₓ)-based inorganic films, but embodiments are not limited thereto.

The ninth interlayer insulating layer INS9 may be disposed on the eighth interlayer insulating layer INS8 and the eighth metal layers ML8. The ninth interlayer insulating layer INS9 may be formed as a silicon oxide (SiOₓ)-based inorganic film, but embodiments are not limited thereto.

Each of the ninth vias VA9 may penetrate through the ninth interlayer insulating layer INS9 to be connected to the exposed eighth metal layer ML8. Each of the ninth vias VA9 may be made of any one of copper (Cu), aluminum (Al), tungsten (W), molybdenum (Mo), chromium (Cr), gold (Au), titanium (Ti), nickel (Ni), and neodymium (Nd), or alloys thereof.

The light emitting element layer LEL may be disposed on the light emitting element backplane EBP. The light emitting element layer LEL may include a bank structure (or bank member) BNS, a light emitting element ED, a residual pattern layer RSD, and a pixel defining layer PDL.

The display panel 410 according to an embodiment may include an emission area EA and a non-emission area NLA. The emission area EA and the non-emission area NLA may be positioned within the display area DA in FIG. 4.

The emission area EA may include a first emission area EA1, a second emission area EA2, and a third emission area EA3 that emit light of different colors. The first to third emission areas EA1, EA2, and EA3 may emit red light, green light, or blue light, respectively, and colors of the light emitted from the first to third emission areas EA1, EA2, and EA3 may be different from each other according to types of light emitting elements ED to be described later. In an embodiment, the first emission area EA1 may emit the red light, which is light of a first light, the second emission area EA2 may emit the green light, which is light of a second color, and the third emission area EA3 may emit the blue light, which is light of a third color, but embodiments are not limited thereto.

The first pixel SP1 may be positioned in a portion overlapping the first emission area EA1, the second pixel SP2 may be positioned in a portion overlapping the second emission area EA2, and the third pixel SP3 may be positioned in a portion overlapping the third emission area EA3.

The non-emission area NLA may prevent each light emitted from the first to third emission areas EA1, EA2, and EA3 from being mixed with each other. The pixel defining layer PDL may be positioned in the non-emission area NLA.

The bank structure BNS according to an embodiment may be positioned in a portion overlapping the emission area EA. The bank structure BNS according to an embodiment may be disposed on the ninth interlayer insulating layer INS9. The bank structure BNS may include a first bank layer BN1 and a second bank layer BN2 that are sequentially stacked.

The first bank layer BN1 according to an embodiment may be positioned on the ninth interlayer insulating layer INS9 and connected to the ninth via VA9. The first bank layer BN1 and the ninth via VA9 may include the same material. The first bank layer BN1 may include a plurality of patterns, and the respective patterns may be separated or spaced apart from each other in the first direction X in portions overlapping the first to third emission areas EA1, EA2, and EA3. For example, the first bank layer BN1 may have island patterns. Each island of the first bank layer BN1 may have a circular shape or a polygonal shape such as a triangular shape or a rectangular shape in plan view.

The second bank layer BN2 according to an embodiment may be disposed on the first bank layer BN1. The second bank layer BN2 may include a plurality of patterns, and the respective patterns may be separated or spaced apart from each other in the first direction X in the portions overlapping the first to third emission areas EA1, EA2, and EA3. In an embodiment, the second bank layer BN2 may have island patterns. Each island of the second bank layer BN2 may have a circular shape or a polygonal shape such as a triangular shape or a rectangular shape in plan view.

The second bank layer BN2 according to an embodiment may have a tip portion TIP protruding toward the non-emission area NLA more than the first bank layer BN1. An undercut portion may be formed between the first bank layer BN1 and the tip portion TIP of the second bank layer BN2. Details will be described below.

The light emitting element ED according to an embodiment may be disposed on the second bank layer BN2. The light emitting element ED may include a first light emitting element ED1 disposed in the first emission area EA1, a second light emitting element ED2 disposed in the second emission area EA2, and a third light emitting element ED3 disposed in the third emission area EA3. The first light emitting element ED1 may include a pixel electrode AND, a first light emitting layer IL1, and a common electrode CAT, the second light emitting element ED2 may include a pixel electrode AND, a second light emitting layer IL2, and a common electrode CAT, and the third light emitting element ED3 may include a pixel electrode AND, a third light emitting layer IL3, and a common electrode CAT.

The first to third light emitting elements ED1, ED2, and ED3 overlapping the first to third emission areas EA1, EA2, and EA3, respectively, may emit light of different colors according to materials of a light emitting layer IL. For example, the first light emitting element ED1 may emit red light, which is light of a first light, the second light emitting element ED2 may emit green light, which is light of a second color, and the third light emitting element ED3 may emit blue light, which is light of a third color. However, embodiments are not limited thereto, and the first to third light emitting elements ED1, ED2, and ED3 overlapping the first to third emission areas EA1, EA2, and EA3, respectively, may also emit light of the same color.

The pixel electrode AND according to an embodiment may be disposed on the second bank layer BN2. The pixel electrode AND may be electrically connected to the ninth via VA9 through the bank structure BNS having conductivity, and be then connected to the drain region DA or source region SR of the transistor PTR through the first to eighth vias VA1 to VA8, the first to eighth metal layers ML1 to ML8, and the contact terminal CTE.

The pixel electrode AND may include a first layer AND1 and a second layer AND2 including different metals. Details will be described below.

A residual pattern layer RSD according to an embodiment may be disposed on the ninth interlayer insulating layer INS9 in a portion overlapping the non-emission area NLA. Details will be described below.

The pixel defining layer PDL according to an embodiment may be positioned on the ninth interlayer insulating layer INS9 in a portion overlapping the non-emission area NLA. The bank structure BNS, the pixel electrode AND, and the light emitting layer IL according to an embodiment may be insulated and spaced apart from each other in the first direction X with the pixel defining layer PDL interposed therebetween.

The light emitting layer IL according to an embodiment may be positioned on the pixel electrode AND. The light emitting layer IL according to an embodiment may include a first light emitting layer IL1, a second light emitting layer IL2, and a third light emitting layer IL3 positioned to respectively overlap the first to third emission areas EA1, EA2, and EA3. The first to third light emitting layers IL1, IL2, and IL3 may emit different light. The light emitting layer IL according to an embodiment may be formed of an organic material and formed by a photolithography process during the manufacturing process. The manufacturing method will be described below.

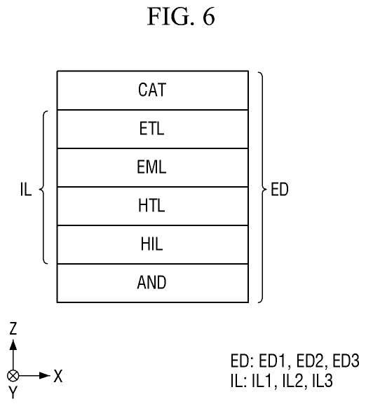

FIG. 6 is an enlarged schematic cross-sectional view schematically illustrating a light emitting element ED in FIG. 5. As illustrated in FIG. 6, the light emitting layer IL according to an embodiment may include a hole injection layer HIL, a hole transporting layer HTL, an organic light emitting layer EML, and an electron transporting layer ETL. According to the embodiment, the hole injection layer HIL and the hole transporting layer HTL may be formed as one layer to form a hole injection and transporting layer. The light emitting layer IL illustrated in FIG. 6 may include a first light emitting layer IL1, a second light emitting layer IL2, and a third light emitting layer IL3 illustrated in FIG. 5.

The hole injection layer HIL may have a single layer made of a single material, a single layer made of different materials, or a multilayer structure having a plurality of layers each made of different materials. As an example, the hole injection layer HIL may include a phthalocyanine compound such as copper phthalocyanine, DNTPD(N,N′-diphenylN,N′-bis-[4-(phenyl-m-tolyl-amino)-phenyl]-biphenyl-4,4′-diamine), m-MTDATA 4,4′,4″-tris(3methylphenylphenylamino)triphenylamine), TDATA(4,4′4″-Tris(N,N-diphenylamino)triphenylamine), 2TNATA(4,4′,4″-tris {N,-(2-naphthyl)-N-phenylamino}-triphenylamine), PEDOT/PSS(Poly (3,4-ethylenedioxythiophene)/Poly (4-styrenesulfonate)), PANI/DBSA(Polyaniline/Dodecylbenzenesulfonic acid), PANI/CSA(Polyaniline/Camphor sulfonicacid), PANI/PSS((Polyaniline)/Poly (4-styrenesulfonate)), etc. However, embodiments are not limited thereto.

The hole transporting layer HTL may have a single layer made of a single material, a single layer made of different materials, or a multilayer structure having a plurality of layers each made of different materials. As an example, the hole transporting layer HTL may include carbazole-based derivatives such as N-phenylcarbazole and polyvinylcarbazole; fluorene-based derivatives, triphenylamine-based derivatives such as TPD(N,N′-bis(3-methylphenyl)-N,N′-diphenyl-[1,1-biphenyl]-4,4′-diamine), TCTA(4,4′,4″-tris(Ncarbazolyl)triphenylamine), or the like, NPB(N,N′-di (1-naphthyl)-N,N′-diphenylbenzidine), TAPC(4,4′-Cyclohexylidene bis[N,N-bis(4-methylphenyl)benzenamine]), or the like. However, embodiments are not limited thereto.

The organic light emitting layer EML may include a host material and a dopant material. The host material is not limited as long as it is a commonly used material, but, for example, Alq3(tris (8-hydroxyquinolino)aluminum), CBP(4,4′-bis(N-carbazolyl)-1,1′-biphenyl), PVK(poly (n-vinylcabazole)), ADN(9,10-di(naphthalene-2-yl)anthracene), TCTA(4,4′,4″-Tris(carbazol-9-yl)-triphenylamine), TPBi(1,3,5-tris (N-phenylbenzimidazole-2-yl)benzene), TBADN(3-tert-butyl-9,10-di(naphth-2-yl) anthracene), DSA(distyrylarylene), CDBP(4,4′-bis(9-carbazolyl)-2,2″-dimethyl-biphenyl), MADN(2-Methyl-9,10-bis(naphthalen-2-yl)anthracene), etc. may be used.

The organic light emitting layer EML may emit light of different colors according to the type of dopant material and materials it contains. As an example, in case that the organic light emitting layer EML emits red light, the organic light emitting layer EML may include a fluorescent material including perylene or PBD:Eu(DBM)3(Phen)(tris(dibenzoylmethanato)phenanthoroline europium). For example, the included dopant material may be selected from, for example, a metal complex or an organometallic complex such as PIQIr(acac)(bis(1-phenylisoquinoline)acetylacetonate iridium), PQIr(acac)(bis(1-phenylquinoline)acetylacetonateiridium), PQIr(tris (1-phenylquinoline)iridium), and PtOEP(octacthylporphyrin platinum).

As an example, in case that the organic light emitting layer EML emits green light, the organic light emitting layer EML may include a fluorescent material including tris(8-hydroxyquinolino)aluminum (Alq3). For example, the included dopant material may be selected from, for example, a metal complex or an organometallic complex such as Ir(ppy)3(fac-tris(2-phenylpyridine)iridium).

As an example, in case that the organic light emitting layer EML emits blue light, the organic light emitting layer EML may include a fluorescent material including any one selected from the group consisting of spiro-DPVBi, spiro-6P, distyryl-benzene (DSB), distyryl-arylene (DSA), polyfluorene (PFO)-based polymers, and poly (p-phenylene vinylene) (PPV)-based polymers. For example, the included dopant material may be selected from, for example, a metal complex or an organometallic complex such as (4,6-F2ppy)2Irpic. However, the materials included in the organic light emitting layer EML are only examples and are not limited thereto.

The electron transporting layer ETL may be disposed on the organic light emitting layer EML. The electron transporting layer ETL may function to inject and transport electrons transferred from the common electrode CAT to the light emitting layer IL. As an example, the electron transporting layer ETL may include an electron transport material such as Alq3(Tris (8-hydroxyquinolinato)aluminum), TPBi(1,3,5-Tri (1-phenyl-1H-benzo[d]imidazol-2-yl)phenyl), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate), ADN(9,10-di(naphthalene-2-yl)anthracene), and a mixture thereof, and lanthanide metals such as LiF, LiQ (Lithium quinolate), Li₂O, BaO, NaCl, CsF, Yb, or halogenated metals such as RbCl and RbI, but embodiments are not limited thereto.

Referring to FIGS. 5 and 6, the common electrode CAT may be disposed on the light emitting layer IL and the pixel defining layer PDL. The common electrode CAT may be positioned in a portion overlapping the emission area EA and the non-emission area NLA. For example, the common electrode CAT may be formed (e.g., entirely formed) on the light emitting layer IL and the pixel defining layer PDL.

The common electrode CAT may include a transparent conductive material to emit the light generated from the light emitting layer IL. The common electrode CAT may receive a common voltage or a low potential voltage. In case that the pixel electrode AND receives a voltage corresponding to a data voltage and the common electrode CAT receives the low potential voltage, a potential difference may be formed between the pixel electrode AND and the common electrode CAT, such that the light emitting layer IL may emit the light.

As an example, the common electrode CAT may be made of a transparent conductive oxide (TCO) such as ITO or IZO capable of transmitting light therethrough or a semi-transmissive conductive material such as magnesium (Mg), silver (Ag), or an alloy of magnesium (Mg) and silver (Ag). In case that the common electrode CAT is made of the semi-transmissive conductive material, light emission efficiency of each of the first to third pixels SP1, SP2, and SP3 may be increased by a micro cavity.

The encapsulation layer TFE according to an-embodiment may be disposed on the light emitting element layer LEL. The encapsulation layer TFE may include at least one inorganic film in order to prevent oxygen or moisture from permeating into the light emitting element layer LEL. For example, the encapsulation layer TFE may include at least one organic film in order to protect the light emitting element layer LEL from foreign substances such as dust. The encapsulation layer TFEL may include a first encapsulation layer TFE1, a second encapsulation layer TFE2, and a third encapsulation layer TFE3 that are sequentially stacked. The first encapsulation layer TFE1 may be disposed on the common electrode CAT, the second encapsulation layer TFE2 may be disposed on the first encapsulation layer TFE1, and the third encapsulation layer TFE3 may be disposed on the second encapsulation layer TFE2.

The first encapsulation layer TFEL and the third encapsulation layer TFE3 may be made of an inorganic insulating material. As an example, the first encapsulation layer TFE1 and the third encapsulation layer TFE3 may include silicon nitride (SiNₓ), silicon oxynitride (SiOₓN_{y}), silicon oxide (SiOₓ), titanium oxide (TiOₓ), and aluminum oxide (AlOₓ).

The second encapsulation layer TFE2 may be made of an organic material. As an example, the second encapsulation layer TFE2 may include an acrylic resin, an epoxy resin, a silicone resin, a silicone acrylic resin, a phenolic resin, a polyamide resin, a polyimide resin, or the like.

An adhesive layer ADL may be a layer for adhering the encapsulation layer TFE and the optical layer OPL to each other. The adhesive layer ADL may be a double-sided adhesive member. For example, the adhesive layer ADL may be a transparent adhesive member such as a transparent adhesive or a transparent adhesive resin.

The optical layer OPL may include first to third color filters CF1, CF2, and CF3, lenses LNS, and a filling layer FIL.

The first to third color filters CF1, CF2, and CF3 may be disposed on the adhesive layer ADL. The first to third color filters CF1, CF2, and CF3 may include colorants such as dyes or pigments absorbing light of wavelength bands other than light of a specific wavelength band, and may be disposed to correspond to the colors of the light emitting from the emission areas EA.

The first color filter CF1 may be a red color filter overlapping the first emission area EA1 and transmitting only the red light therethrough. The second color filter CF2 may be a green color filter overlapping the second emission area EA2 and transmitting only the green light therethrough, and the third color filter CF3 may be a blue color filter overlapping the third emission area EA3 and transmitting only the blue light therethrough.

The lenses LNS may be disposed on the first color filter CF1, the second color filter CF2, and the third color filter CF3, respectively. The lenses LNS may be structures (or members) for increasing a ratio of light directed to a front surface of the display panel 410. The lenses LNS may have a cross-sectional shape convex in an upward direction.

The filling layer FIL may be disposed on the lenses LNS. The filling layer FIL may have a selected refractive index so that light travels (or transmits) in the third direction Z at an interface between the lenses LNS and the filling layer FIL. For example, the filling layer FIL may be a planarizing layer. The filling layer FIL may be an organic film made of an acrylic resin, an epoxy resin, a phenolic resin, a polyamide resin, a polyimide resin, or the like.

The cover layer CVL may be disposed on the optical layer OPL. The cover layer CVL may be a glass substrate or a polymer resin such as a resin. In case that the cover layer CVL is the glass substrate, the cover layer CVL may be attached onto the filling layer FIL. For example, the filling layer FIL may function to adhere the cover layer CVL. In case that the cover layer CVL is the glass substrate, the cover layer CVL may function as an encapsulation substrate. In case that the cover layer CVL is the polymer resin such as the resin, the cover layer CVL may be applied (e.g., directly applied) onto the filling layer FIL.

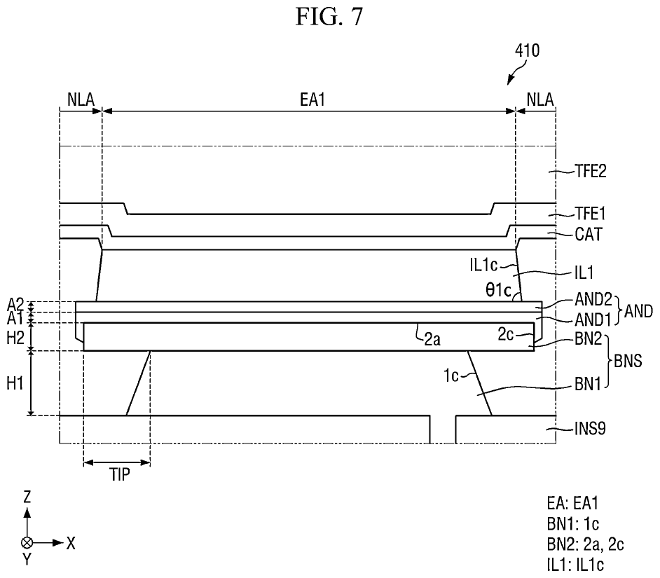

FIG. 7 is an enlarged schematic cross-sectional view schematically illustrating a first emission area EA1 in FIG. 5.

Referring to FIG. 7, the bank structure BNS according to an embodiment may be positioned in a portion overlapping the first emission area EA1. The bank structure BNS according to an embodiment may include a first bank layer BN1 and a second bank layer BN2 having different materials from each other.

The first bank layer BN1 according to an embodiment may be positioned in a portion overlapping the first emission area EA1. The first bank layer BN1 may not overlap the non-emission area NLA.

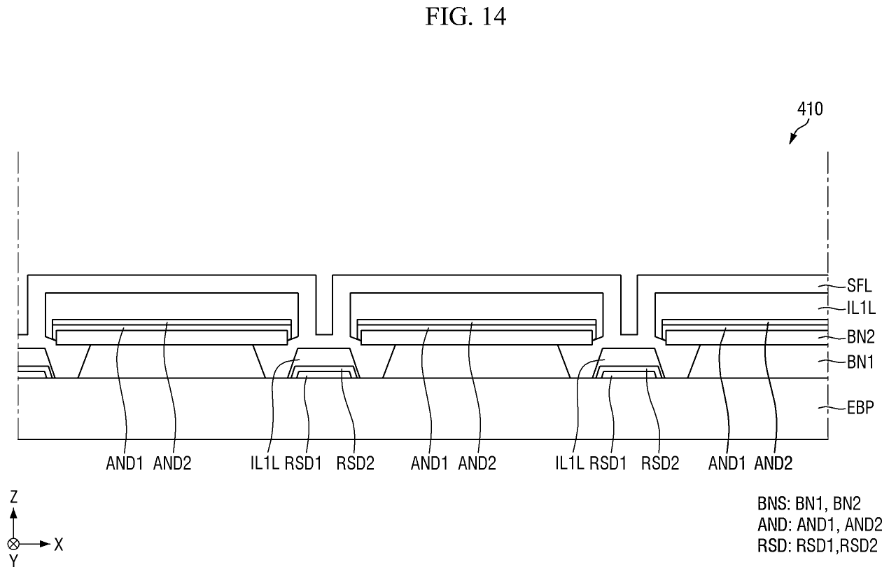

The first bank layer BN1 may be a metal with high etching resistance. For example, the display panel 410 according to an embodiment may include a process of etching a sacrificial layer SFL (see FIG. 14), which will be described later, during the manufacturing process. At this time, the first bank layer BN1 may be a metal that has high etching resistance to an etchant used in the etching process. As an example, the first bank layer BN1 may be titanium (Ti). The etchant described above may include any liquid or gas used in the etching process. The manufacturing process will be described later.

In some embodiments, the first bank layer BN1 may include a side surface 1c. The side surface 1c of the first bank layer BN1 may be a surface facing the non-emission area NLA. The side surface 1c of the first bank layer BN1 may be depressed (or recessed) toward the center portion of the emission area EA rather than a side surface 2c of the second bank layer BN2. The side surface 1c of the first bank layer BN1 may be covered (e.g., entirely covered) by the pixel defining layer PDL, and the side surface 1c of the first bank layer BN1 may be in contact with (e.g., entirely in contact with) the pixel defining layer PDL.

The second bank layer BN2 according to an embodiment may be positioned in a portion overlapping the first emission area EA1. The second bank layer BN2 may overlap a portion of the non-emission area NLA.

The second bank layer BN2 may be a metal with higher etching resistance than the first bank layer BN1. For example, the etch rate of the second bank layer BN2 may be lower than that of the first bank layer BN1 in the same etching process. As a result, the second bank layer BN2 may have a tip portion TIP that protrudes more than the first bank layer BN1 in the same etching process, and an undercut portion may be formed between the side surface 1c of the first bank layer BN1 and the tip portion TIP of the second bank layer BN2. For example, the second bank layer BN2 may be a metal that has etching resistance to an etchant used in the etching process of a sacrificial layer SFL (see FIG. 14), which will be described later. For example, the second bank layer BN2 may include any one of niobium (Nb), vanadium (V), and tantalum (Ta). The manufacturing process will be described later.

In some embodiments, the second bank layer BN2 may include an upper surface 2a and a side surface 2c. The upper surface 2a and the side surface 2c of the second bank layer BN2 may be covered by the pixel electrode AND and may be in contact with the pixel electrode

AND. In some cases, a portion of the side surface 2c of the second bank layer BN2 may be in contact with the pixel defining layer PDL.

In some embodiments, a height H1 of the first bank layer BN1 may be greater than a height H2 of the second bank layer BN2. For example, the height H1 of the first bank layer BN1 may be about 1,500 angstroms or more and about 2,500 angstroms or less, and the height H2 of the second bank layer BN2 may be about 1,000 angstroms or more and about 2,000 angstroms or less. Within the range described above, the height H1 of the first bank layer BN1 may be greater than the height H2 of the second bank layer BN2.

The pixel electrode AND according to an embodiment may be positioned in a portion that overlaps the emission area EA and the non-emission area NLA. Since the second bank layer BN2 includes a tip portion TIP, the pixel electrode AND according to an embodiment may be formed by disconnecting a portion overlapping each emission area EA without a separate etching process.

The pixel electrode AND may include a first layer AND1 including a metal and a second layer AND2 disposed on the first layer AND1 and including transparent conductive oxide (TCO). As an example, the first layer AND1 may include any one of copper (Cu), aluminum (Al), tungsten (W), molybdenum (Mo), chromium (Cr), gold (Au), titanium (Ti), nickel (Ni), and neodymium (Nd), and the second layer AND2 may include one or more of indium tin oxide (ITO), indium zinc oxide (IZO), indium tin zinc oxide (ITZO), zinc indium tin oxide (ZITO), indium gallium zinc oxide (IGZO), indium tin oxide (ITO), and zinc tin oxide (ZTO). It has been illustrated in FIGS. 5 and 6 that the pixel electrode AND has a multilayer structure, but the pixel electrode AND may also be formed to have a single-layer structure according to embodiments.

In some embodiments, the first layer AND1 may be disposed on the upper surface 2a and the side surface 2c of the second bank layer BN2. The first layer AND1 may cover (e.g., entirely cover) the upper surface 2a of the second bank layer BN2 and may be in contact with the entire upper surface 2a of the second bank layer BN2. For example, the first layer AND1 may cover a portion of the side surface 2c of the second bank layer BN2 and may be in contact with a portion of the side surface 2c of the second bank layer BN2. For convenience of explanation, the drawing illustrates the second layer AND2 not covering the side surface 2c of the second bank layer BN2, but embodiments are not limited thereto. According to the process conditions, the second layer AND2 may cover the side surface 2c of the second bank layer BN2 on the first layer AND1.

In some embodiments, a height A1 of the first layer AND1 may be greater than a height A2 of the second layer AND2. For example, the height A1 of the first layer AND1 may be about 500 angstroms, and a height A2 of the second layer AND2 may be about 70 angstroms, but embodiments are not limited thereto.

The first layer AND1 and the second layer AND2 may be covered by the pixel defining layer PDL in a portion overlapping the non-emission area NLA.

A first light emitting layer IL1 may be positioned on the second layer AND2 of the pixel electrode AND.

In some embodiments, the first light emitting layer IL1 may include a side surface IL1c facing the non-emission area NLA. The side surface IL1c of the first light emitting layer IL1 may be an inclined surface. For example, the side surface IL1c of the first light emitting layer IL1 may be inclined between the first direction (e.g., X-axis direction) and the third direction (e.g., Z-axis direction).

In an embodiment, the side surface IL1c of the first light emitting layer IL1 may be inclined in a cross-section. The first light emitting layer IL1 according to an embodiment may be formed by a photolithography process during the manufacturing process. Accordingly, the side surface IL1c of the first light emitting layer IL1 may be inclined in a cross-section without tail defects due to mask shadows. For example, the side surface IL1c of the first light emitting layer IL1 may have a high taper angle. For example, an inclination angle θ1c formed by the side surface IL1c of the first light emitting layer IL1 and the pixel defining layer PDL may be in a range of about 60 degrees to about 90 degrees.

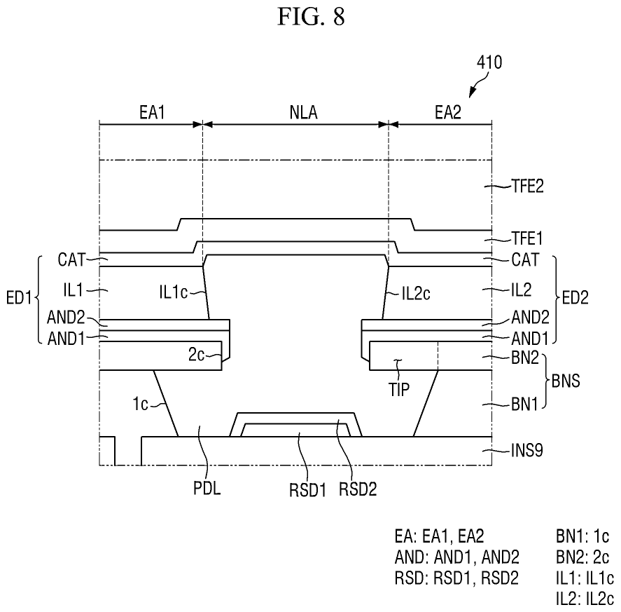

The common electrode CAT, the first encapsulation layer TFE1, and the second encapsulation layer TFE2 may be formed on the entire surface of the first light emitting layer IL1 and the pixel defining layer PDL. The common electrode CAT, the first encapsulation layer TFE1, and the second encapsulation layer TFE2 may overlap the tip portion TIP of the second bank layer BN2 in the third direction Z. Other redundant explanations will be omitted. FIG. 8 is an enlarged schematic cross-sectional view schematically illustrating a non-emission area NLA positioned between the first emission area EA1 and the second emission area EA2 of FIG. 5.

Referring to FIG. 8, the first emission area EA1 and the second emission area EA2 may be spaced apart from each other with the non-emission area NLA interposed therebetween.

A residual pattern layer RSD according to an embodiment may be positioned on the ninth interlayer insulating layer INS9 in a portion overlapping the non-emission area NLA. The residual pattern layer RSD may be formed in a manufacturing process of the pixel electrode AND, because a material forming the pixel electrode AND is disconnected from the pixel electrode AND rather than being connected to the pixel electrode AND, by the tip of the second bank layer BN2. Accordingly, the residual pattern layer RSD and the pixel electrode AND may include the same material.

In case that the pixel electrode AND has the multilayer structure, a stacked structure of residual pattern layer RSD may be the same as a stacked structure of the pixel electrode AND. As an example, the residual pattern layer RSD may include a first residual pattern layer RSD1 including the same material as the first layer AND1 of the pixel electrode AND and a second residual pattern layer RSD2 including the same material as the second layer AND2 of the pixel electrode AND. The second residual pattern layer RSD2 may cover the first residual pattern layer RSD1.

The pixel defining layer PDL according to an embodiment may be positioned on the ninth interlayer insulating layer INS9 and the residual pattern layer RSD. The pixel defining layer PDL may cover (e.g., entirely cover) the residual pattern layer RSD. The pixel defining layer PDL may planarize the step between the bank structures BNS positioned by overlapping each of the first and second emission areas EA1 and EA2, and planarize the step between the first light emitting element ED1 and the second light emitting element ED2.

The pixel defining layer PDL may include an inorganic material with fluidity or an organic material. As an example, in case that the pixel defining layer PDL is an organic material, the pixel defining layer PDL may include any one of silicon-based, epoxy-based, acrylic-based, and silicon-acrylic-based materials, and in case that the pixel defining layer PDL is an inorganic material, the pixel defining layer PDL may be hexamethyl disiloxane (HMDSO).

In some embodiments, the pixel defining layer PDL may cover (e.g., entirely cover) the side surface 1c of the first bank layer BN1 and may be in contact with the entire side surface 1c of the first bank layer BN1. For example, the pixel defining layer PDL may cover (e.g., entirely cover) the side surface 2c of the second bank layer BN2 and may be in contact with a portion of the side surface 2c of the second bank layer BN2. For example, the pixel defining layer PDL may cover (e.g., entirely cover) a side surface IL1c of the first light emitting layer IL1 and a side surface IL2c of the second light emitting layer IL2, and may be in contact with the entire side surface IL1c of the first light emitting layer IL1 and the side surface IL2c of the second light emitting layer IL2.

The common electrode CAT, the first encapsulation layer TFE1, and the second encapsulation layer TFE2 according to an embodiment may overlap the residual pattern layer RSD in the third direction Z. Other redundant explanations will be omitted.

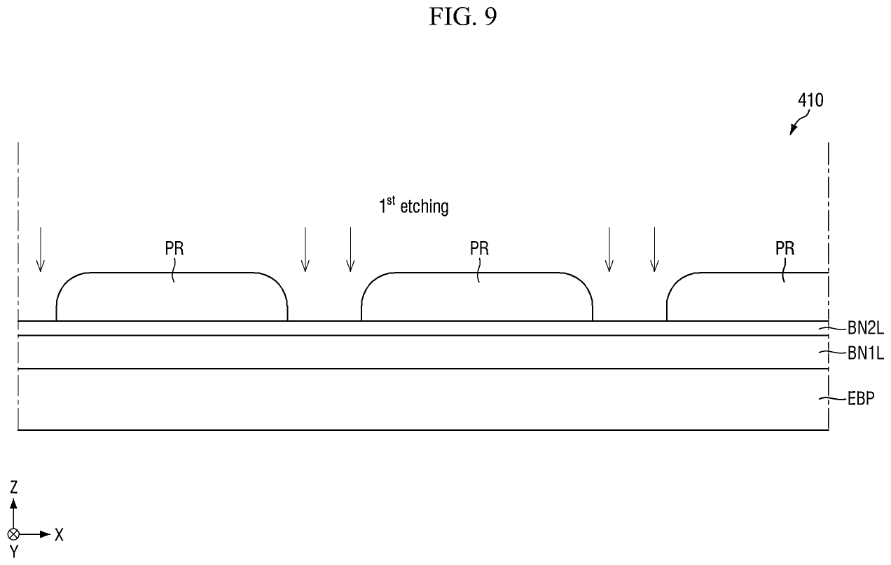

FIGS. 9 to 21 are schematic cross-sectional views illustrating a method for manufacturing a light emitting element layer LEL and an encapsulation layer TFE in FIG. 5. Hereinafter, the formation order of each layer of the light emitting element layer LEL and the encapsulation layer TFE will be described.

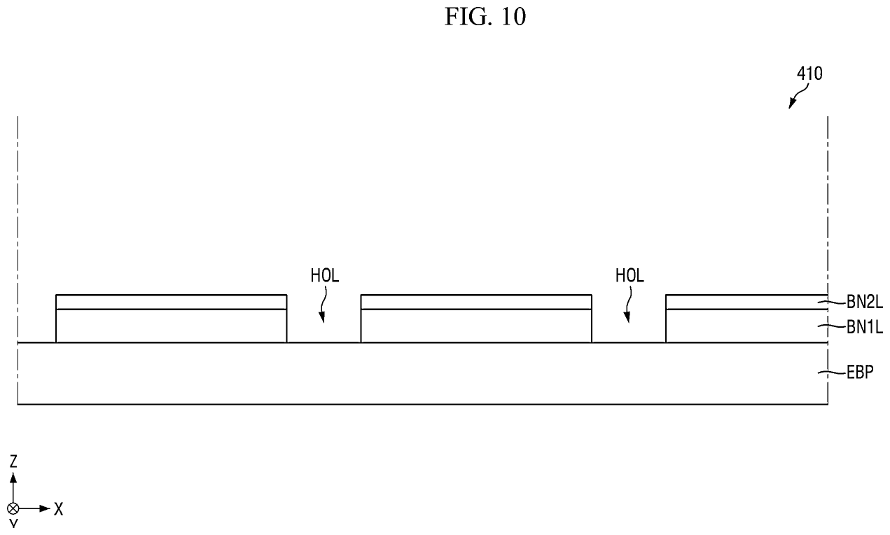

Referring to FIGS. 9 and 10, a first bank material layer BN1L and a second bank material layer BN2L may be sequentially formed on a light emitting element backplane EBP. The detailed structure of the light emitting element backplane EBP is the same as described above with reference to FIG. 5. Redundant description of the light emitting element backplane EBP will be omitted.

Subsequently, a photoresist PR may be formed on the second bank material layer BN2L. The photoresist PR may be provided in plural numbers, and the photoresists PR may be spaced apart from each other.

Next, a first etching process (e.g., 1^{st} etching) may be performed using the photoresists PR as masks. As an example, the first etching process (e.g., 1^{st} etching) may be a dry etching process. In this process, the first bank material layer BN1L and the second bank material layer BN2L in the portion where the photoresist PR is not formed may be isotropically removed, and a hole HOL may be formed in a portion where the first bank material layer BN1L and the second bank material layer BN2L are removed. The light emitting element backplane EBP may be exposed in a portion overlapping the hole HOL.

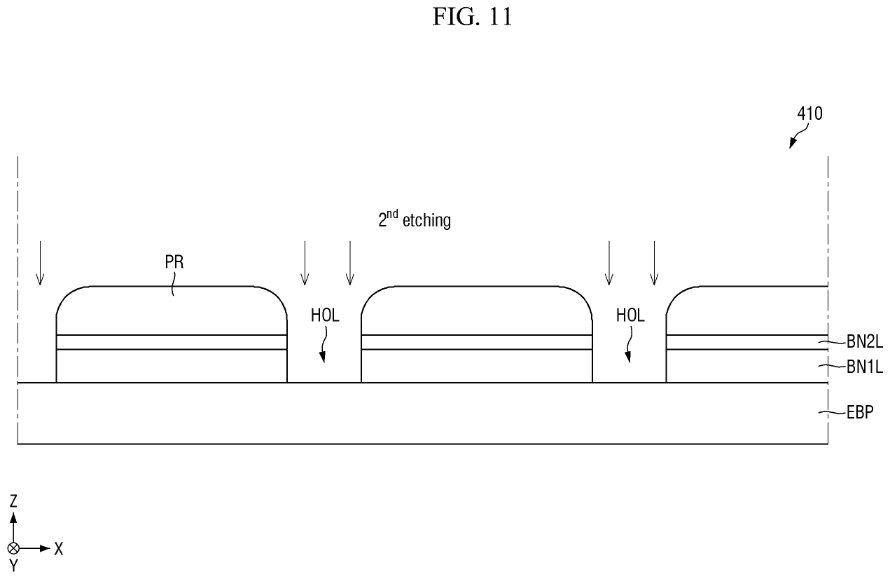

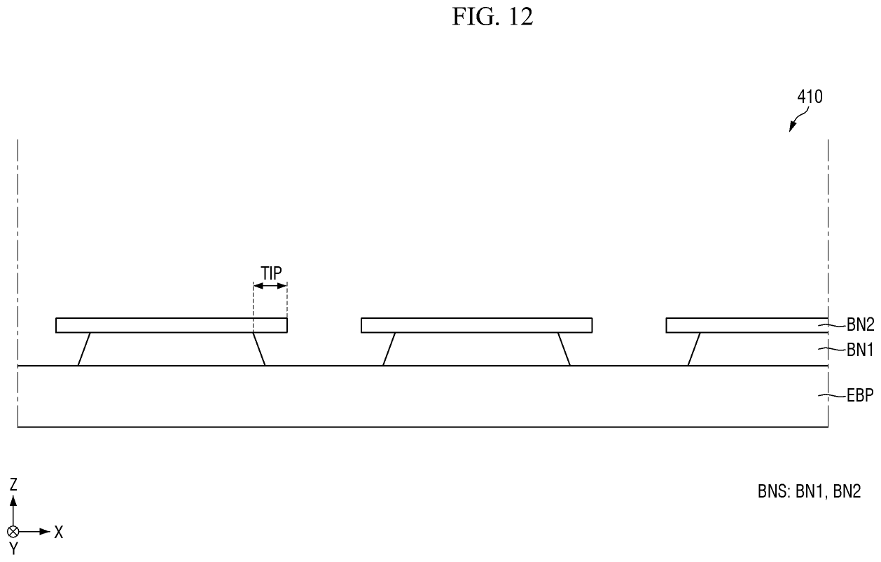

Subsequently, referring to FIGS. 11 and 12, a photoresist PR may be formed in the same portion as the first etching process (e.g., 1^{st} etching), and a second etching process (e.g., 2^{nd} etching) may be performed using the photoresists PR as masks. As an example, the second etching process (e.g., 2^{nd} etching) may be a wet etching process.

In this process, the first bank material layer BN1L and the second bank material layer BN2L overlapping inside the hole HOL may be removed anisotropically. For example, the first bank material layer BN1L according to an embodiment may include a material that has a higher etch rate than the second bank material layer BN2L. Accordingly, the first bank material layer BN1L may have a side surface recessed in the first direction X than the second bank material layer BN2L through the second etching process (e.g., 2^{nd} etching). For example, the side surface of the second bank material layer BN2L may protrude in the first direction X than the side surface of the first bank material layer BN1L.

In this process, the first bank material layer BN1L and the second bank material layer BN2L may be formed in the shapes of the bank structure BNS including the first bank layer BN1 and the second bank layer BN2 shown in FIG. 5. For example, the second bank layer BN2 may have a tip portion TIP protruding from the side surface of the first bank layer BN1, and an undercut portion may be formed between the side surface of the first bank layer BN1 and the tip portion TIP of the second bank layer BN2.

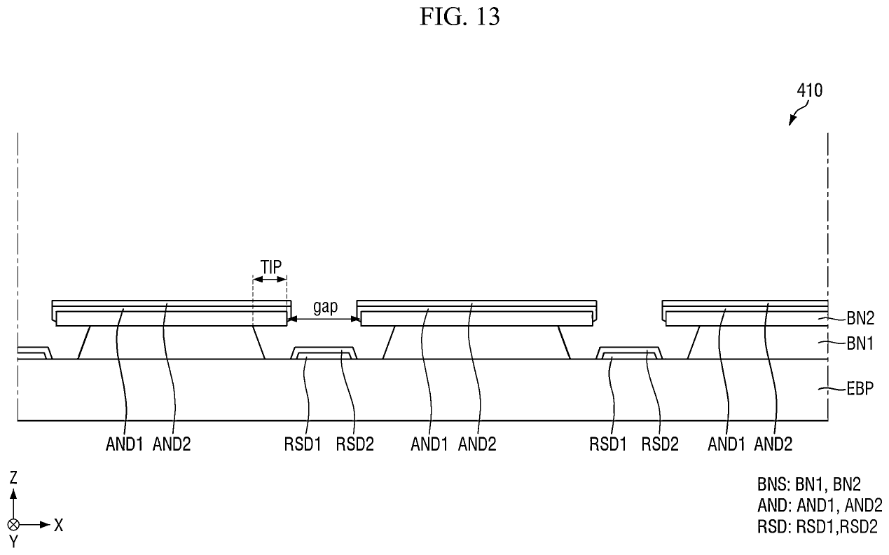

Subsequently, referring to FIG. 13, a pixel electrode AND may be formed on the second bank layer BN2. The pixel electrode AND may be formed by a sputtering process and thermal evaporation method. Materials forming the pixel electrode AND according to an embodiment may be formed to be spaced apart from each other on the bank structures BNS without a separate etching process since the second bank layer BN2 includes the tip portion TIP. For example, the display panel 410 according to an embodiment may provide process case and process simplicity in the manufacturing process of the pixel electrode AND. For example, since the process forming the pixel electrode AND according to an embodiment does not require a separate etching process, the gap between the pixel electrodes AND may be formed to be narrow.

In this process, the material forming the pixel electrode AND may also be positioned on the light emitting element backplane EBP in a portion not overlapping the bank structure

BNS. The material forming the pixel electrode AND formed on the light emitting element backplane EBP may be formed in a shape of the residual pattern layer RSD. According to the embodiment, the pixel electrode AND may include a first layer AND1 and a second layer AND2, and accordingly, the residual pattern layer RSD may include a first residual pattern layer RSD1 and a second residual pattern layer RSD2.

Subsequently, referring to FIG. 14, a first light emitting material layer IL1L may be formed on the bank structure BNS and the residual pattern layer RSD. The first light emitting material layer IL1L may be formed (e.g., entirely formed) on the bank structure BNS and the residual pattern layer RSD. However, since the bank structure BNS according to an embodiment has an undercut structure, the first light emitting material layer IL1L may be formed to be spaced apart from each other on the pixel electrodes AND. For example, the first light emitting material layer IL1L positioned on the residual pattern layer RSD and the first light emitting material layer IL1L positioned on the pixel electrode AND may be spaced apart from each other.

Next, a sacrificial layer SFL may be formed on the first light emitting material layer IL1L. The sacrificial layer SFL may cover the entire first light emitting material layer IL1L. In case that the sacrificial layer SFL undergoes through the subsequent etching process, the first light emitting material layer IL1L may be protected from the etchant. The sacrificial layer SFL may be formed (e.g., directly formed) on the first light emitting material layer IL1L and may include a metal material. As an example, the sacrificial layer SFL may include aluminum (Al), but embodiments are not limited thereto.

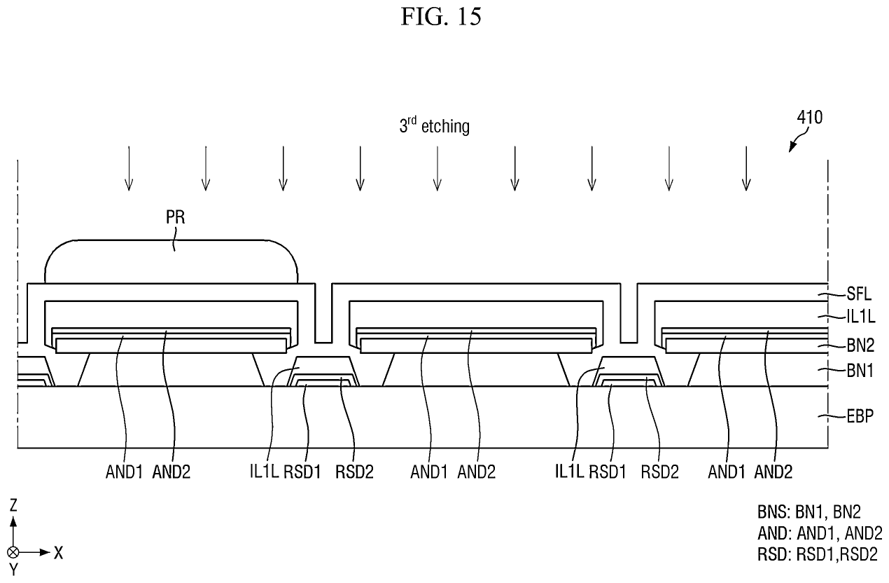

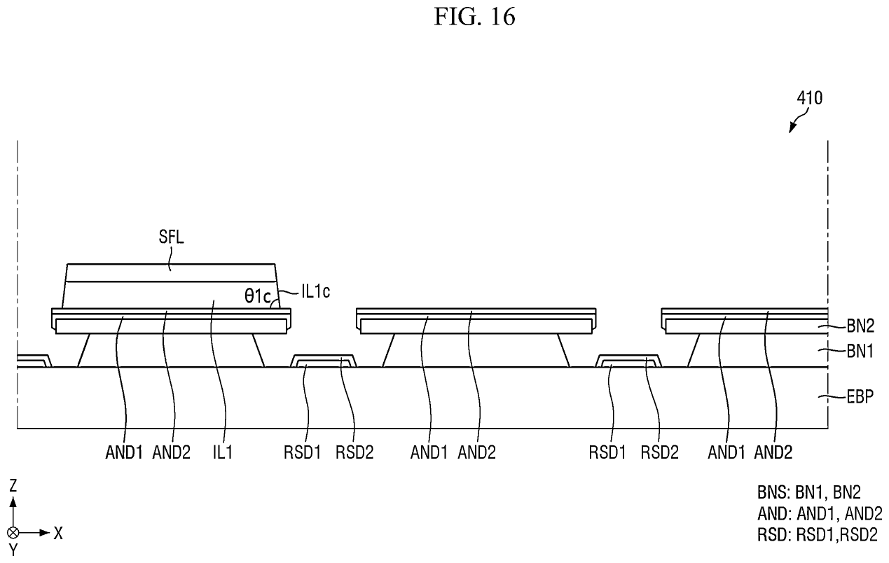

Next, referring to FIGS. 15 and 16, a photoresist PR may be formed on the pixel electrode AND, and a third etching process (e.g., 3^{rd} etching) may be performed using the photoresist PR as a mask. The photoresist PR may be positioned on the sacrificial layer SFL.

In this process, a portion of the sacrificial layer SFL and the first light emitting material layer IL1L where the photoresist PR is not formed may be removed. The third etching process (e.g., 3^{rd} etching) may be proceeded in a single dry etching process or performed alternately through a dry etching process and a wet etching process. In this process, the first light emitting material layer IL1L may be formed as a first light emitting layer IL1, and the sacrificial layer SFL may be positioned on the first light emitting layer IL1.

The first bank layer BN1 and the second bank layer BN2 according to an embodiment may include a material that is highly resistant to the etchant included in the third etching process (e.g., 3^{rd} etching). Accordingly, damage to the first bank layer BN1 and the second bank layer BN2 in this process may be minimized. Since the materials have been described above, descriptions thereof will be omitted.

The first light emitting layer IL1 according to an embodiment may be formed by the third etching process (e.g., 3^{rd} etching) without a separate fine metal mask, and thus, may have a side surface IL1c, which is inclined in a cross-sectional shape without tail defects and mask shadow defects. For example, a high taper angle may be formed between the side surface IL1c of the first light emitting layer IL1 and the pixel electrode AND. As an example, the inclination angle θ1c formed by the side surface IL1c of the first light emitting layer IL1 may be in a range of about 60 degrees to about 90 degrees.

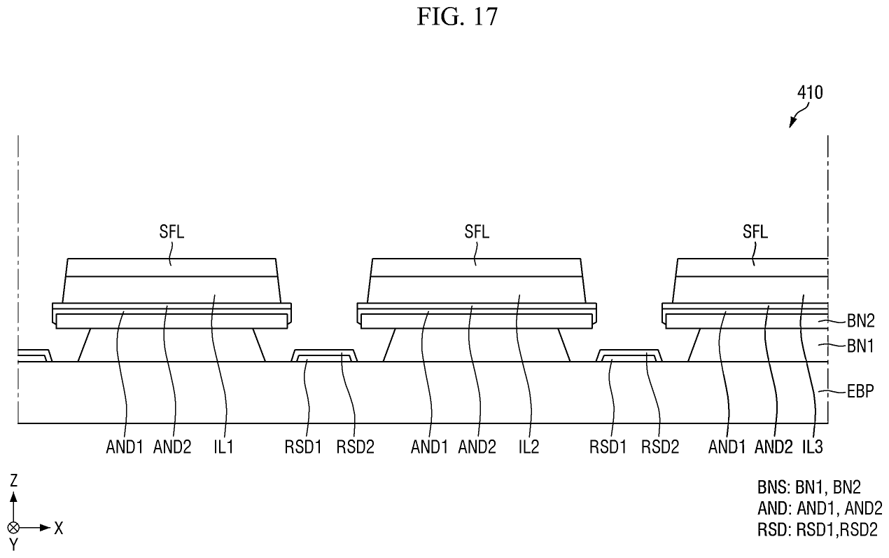

Next, referring to FIG. 17, the process described above is repeated to form a second light emitting layer IL2 and a third light emitting layer IL3. The second light emitting layer IL2 and the third light emitting layer IL3 according to an embodiment may include the same structure and characteristics as the first light emitting layer IL1. Redundant explanations will be omitted.

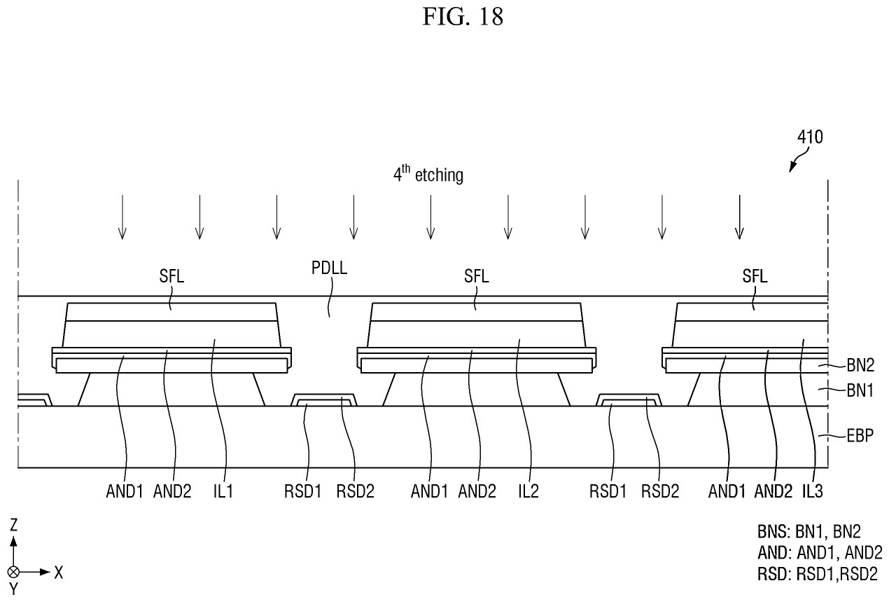

Next, referring to FIGS. 18 to 20, a pixel defining material layer PDLL may be formed on the sacrificial layer SFL and the residual pattern layer RSD. The pixel defining material layer PDLL may fill the undercut portion of the bank structure BNS and cover (e.g., entirely cover) the residual pattern layer RSD. For example, the pixel defining material layer PDLL may planarize a step positioned between the first light emitting layer IL1 and the second light emitting layer IL2 and a step positioned between the second light emitting layer IL2 and the third light emitting layer IL3.

Subsequently, a fourth etching process (e.g., 4^{th} etching) may be performed on the entire surface of the pixel defining material layer PDLL. The fourth etching process (e.g., 4^{th} etching) may be performed alternately through a dry etching process and a wet etching process.

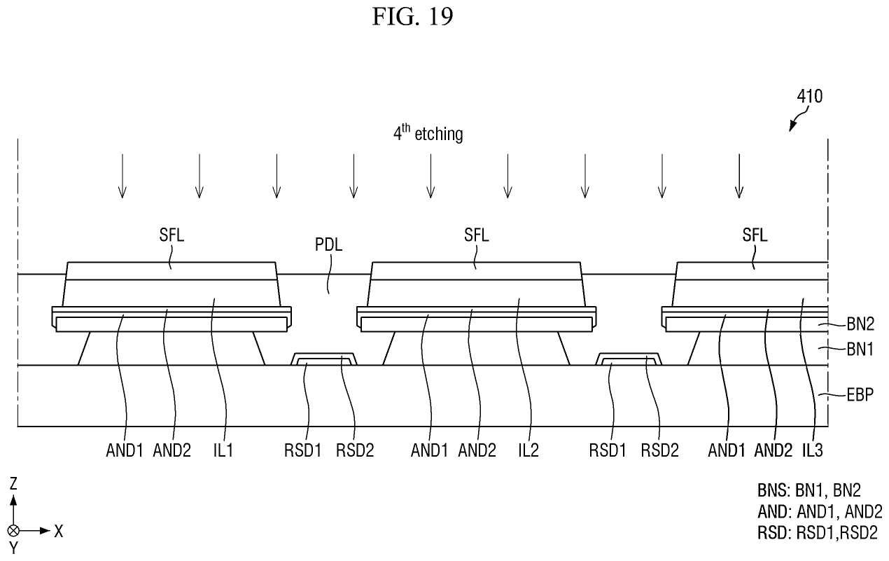

As illustrated in FIG. 19, a dry etching process may be first performed to remove a portion of the pixel defining material layer PDLL. The dry etching process may be performed until the sacrificial layer SFL is exposed. In this process, the pixel defining material layer PDLL may be formed in the shape of the pixel defining layer PDL shown in FIG. 5.

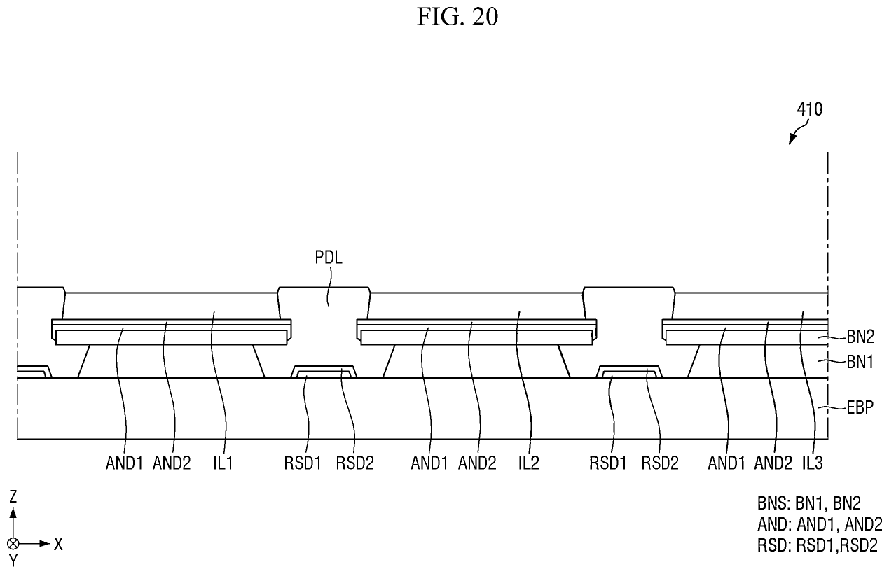

As illustrated in FIG. 20, a wet etching process may be secondly performed to remove a portion of the sacrificial layer SFL. In this process, the sacrificial layer SFL may be removed (e.g., entirely removed) and the first to third light emitting layers IL1, IL2, and IL3 may be exposed.

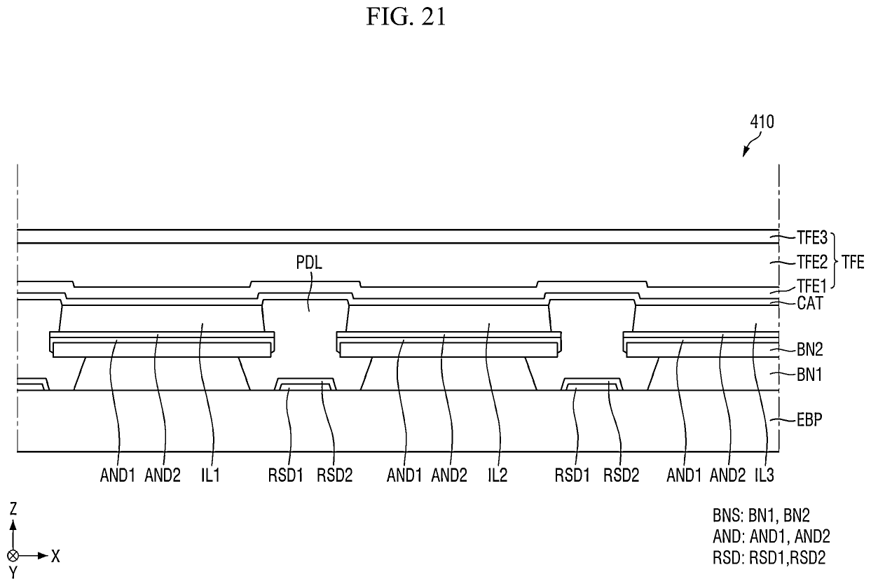

Referring to FIG. 21, the display panel 410 may be manufactured by sequentially stacking a common electrode CAT and an encapsulation layer TFE on the light emitting layer IL and the pixel defining layer PDL. Since the description of the common electrode CAT and the encapsulation layer TFE is the same as described above with reference to FIG. 5, detailed description thereof will be omitted.

A display device 10 of an embodiment may include, in a portion overlapping a non-display area NDA, a power connection electrode which is connected to a pixel electrode AND and a pixel defining layer PDL, a residual pattern layer RSD and a bank structure BNS which completely cover the power connection electrode. Therefore, it is possible to solve corrosion defects of the power connection electrode caused by a fabrication process of the display device 10.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a substrate including an emission area and a non-emission area;
a bank member disposed on the emission area of the substrate and including an undercut portion;
a pixel electrode disposed on the bank member;
a light emitting layer on the pixel electrode;
a residual pattern layer disposed in the non-emission area of the substrate and spaced apart from the pixel electrode, the residual pattern layer and the pixel electrode including a same material; and
a pixel defining layer disposed on the residual pattern layer and in contact with the bank member, the pixel electrode and the light emitting layer,
wherein the bank member comprises:
a first bank layer, and
a second bank layer including a tip portion protruding toward the non-emission area more than a side surface of the first bank layer.

2. The display device of claim 1, wherein the first bank layer and the second bank layer include different metals.

3. The display device of claim 2, wherein
the first bank layer includes titanium, and
the second bank layer includes at least one of niobium, vanadium, and tantalum.

4. The display device of claim 2, wherein
the first bank layer includes a first side surface facing the non-emission area, and
an undercut portion is formed between the first side surface of the first bank layer and the tip portion of the second bank layer.

5. The display device of claim 4, wherein the pixel defining layer is in contact with an entire surface of the first side surface of the first bank layer.

6. The display device of claim 5, wherein the pixel defining layer fills the undercut portion formed between the first side surface of the first bank layer and the tip portion of the second bank layer.

7. The display device of claim 6, wherein the pixel defining layer includes at least one of silicon-based, epoxy-based, acrylic-based, and silicon-acrylic-based materials.

8. The display device of claim 6, wherein the pixel defining layer includes hexamethyl disiloxane.

9. The display device of claim 1, wherein a height of the first bank layer is greater than a height of the second bank layer.

10. The display device of claim 9, wherein
the height of the first bank layer is in a range of about 1,500 angstroms to about 2,500 angstroms, and
the height of the second bank layer is in a range of about 1,000 angstroms to about 2,000 angstroms.

11. The display device of claim 1, wherein
the second bank layer includes a first side surface facing the non-emission area and a first surface facing the light emitting layer, and
the pixel electrode entirely covers the first surface and entirely contacts the first surface of the second bank layer.

12. The display device of claim 11, wherein the pixel electrode covers the first side surface of the second bank layer and is in contact with the first side surface of the second bank layer.

13. The display device of claim 1, wherein the pixel electrode comprises:
a first layer disposed on the second bank layer and includes a metal; and
a second layer disposed on the first layer and including a transparent conductive oxide (TCO).

14. The display device of claim 13, wherein
the residual pattern layer comprises a first residual pattern layer and a second residual pattern layer,
the first residual pattern layer and the first layer include a same material,
the second residual pattern layer and the second layer include a same material, and
the second residual pattern layer covers the first residual pattern layer.

15. The display device of claim 14, wherein
the pixel defining layer is in contact with the second residual pattern layer, and
the pixel defining layer entirely covers the residual pattern layer.

16. The display device of claim 1, wherein
the light emitting layer includes a first side surface facing the non-emission area, and
an inclination angle formed by the pixel electrode and the first side surface of the light emitting layer is in a range of about 60 degrees to about 90 degrees.

17. A method of manufacturing a display device, the method comprising:
forming a first bank layer on a substrate, and forming a second bank layer on a first bank layer;
removing a portion of the first bank layer and the second bank layer so that the second bank layer includes a tip portion protruding than a side surface of the first bank layer;
forming a pixel electrode on the second bank layer;
forming a light emitting layer and a sacrificial layer on the pixel electrode, and forming a pixel defining layer on an entire surface of the sacrificial layer;
removing a portion of the pixel defining layer to expose the sacrificial layer; and
removing the sacrificial layer to expose the light emitting layer.

18. The display device of claim 17, wherein, in the removing of the portion of the first bank layer, the first bank layer has a high etch rate in respect to a same etchant than the second bank layer.

19. The display device of claim 18, wherein, in the removing of the sacrificial layer, the first bank layer and the second bank layer have different etching resistances to an etchant removing the sacrificial layer.

20. The display device of claim 19, wherein the light emitting layer is formed by a photolithography process.
